(19) United States
(12) Patent Application Publication
(10) Pub. No.: US 2017/0262180 A1
(43) Pub. Date: Sep. 14, 2017

(54) INTEGRATED CONTROL OF WRITE-ONCE DATA STORAGE DEVICES

(71) Applicant: Burlywood, LLC, Longmont, CO (US)

(72) Inventor: Tod Roland Earhart, Longmont, CO (US)

(21) Appl. No.: 15/450,865

(22) Filed: Mar. 6, 2017

Related U.S. Application Data
(60) Provisional application No. 62/305,332, filed on Mar. 8, 2016.

(51) Int. Cl. G06F 3/06; G11C 16/16; G11C 16/26; G11C 16/34

(52) U.S. Cl. CPC G06F 3/0604; G11C 16/3495; G11C 16/16; G11C 16/3413; G11C 16/3427; G11C 16/26; G06F 3/0688; G06F 3/0655; G06F 3/0652; G06F 17/30188

(57) ABSTRACT

Storage devices, storage controllers, and apparatuses are provided for providing one-time writeable storage devices. In an implementation, a storage device may include a data storage medium including data storage locations and a controller. The controller is coupled to the data storage medium and is configured to receive at least write operations for storage of data onto the data storage medium. The controller is further configured to provide a write-once mode of operation that prevents the data written to ones of the data storage locations of the data storage medium from being overwritten or erased by further data directed for storage to the ones of the data storage locations.

### RELATED APPLICATIONS

This application hereby claims the benefit of and priority to U.S. Provisional Patent Application 62/305,332, titled “WORM IMPLEMENTATION FOR STORAGE DEVICES WITH INTEGRATED CONTROL,” filed Mar. 8, 2016, which is hereby incorporated by reference in its entirety.

### BACKGROUND

Many data storage applications are suitable for WORM (Write Once, Read Many) operation. Some applications require a system with WORM operation to conform to laws and standards, for example SEC regulations (SEC Rule 17-a-4(f)) requiring systems that are tamper-proof and unalterable. WORM data storage has been utilized for broker-dealer records within the Financial Industry Regulatory Authority and the U.S. Securities and Exchange Commission. WORM operation is highly desirable in many applications such as long term archival of high value data, records and retention snapshots, transport of data between companies that should never be altered, etc.

A secure WORM data storage device must not be able to be overwritten, erased, or altered without clear evidence of tampering. WORM data storage devices may be removable or non-removable, and have been available in Tape Libraries and Optical Arrays in both standalone form as well as connected via WAN, SAN, or LAN networks. WORM drives preceded the introduction of the CD Recordable (CD-R) and DVD Recordable (DVD-R) storage devices. An early example was the IBM 3363, which typically used a 12 in (30 cm) disk in a cartridge, with an ablative optical layer that could be written to only once, and were often used in places like libraries that needed to store large amounts of data.

Punched cards and paper tape are examples of obsolete WORM media. Although any unpunched area of the medium could be punched after the first write of the medium, doing so was virtually never useful. Read-only memory (ROM) is also a WORM medium. Such memory may contain the instructions to a computer to read the operating system from another storage device such as a hard disk drive.

### OVERVIEW

With newer interest in WORM data storage and data storage applications, it is desirable to create a new generation of WORM storage devices that have the bandwidth to support current data storage needs while providing both physical and data security.

The present disclosure provides advantages for data storage devices. For NAND-based storage devices that may wear out with erase cycles, the present disclosure at least reduces and possibly eliminates erase cycles to extend storage device life. The present disclosure also provides cost reduction opportunities by eliminating unneeded circuits to support erase voltage generation/distribution and rewrite operations. The present disclosure also allows reduced storage assembly complexity by only dealing with one set of stored write data. Data provisioning, media defect management, and overwritten logical blocks complexity can be avoided, resulting in a simpler, possibly more reliable, and less costly storage device.

In an implementation, a storage device may include a data storage medium including data storage locations and a controller. The controller is coupled to the data storage medium and is configured to receive at least write operations for storage of data onto the data storage medium. The controller is further configured to provide a write-once mode of operation that prevents the data written to ones of the data storage locations of the data storage medium from being overwritten or erased by further data directed for storage to the ones of the data storage locations.

In another implementation, a storage controller is provided. The storage controller includes a processor, configured to receive at least write operations directed to a data storage medium and a memory, coupled to the processor. The memory includes computer-readable instructions that when executed by the processor are configured to direct the processor to at least reject ones of the write operations directed to previously written addresses of the data storage medium and reject incorporation of firmware including further computer-readable instructions that support writing to data storage locations of the data storage medium more than one time by the write operations.

In yet another implementation, an apparatus is provided. The apparatus includes one or more computer readable storage media. Program instructions stored on the one or more computer readable storage media, based at least on being read and executed by a processing system, direct the processing system to at least receive at least write operations for storage of data onto an associated data storage medium, maintain at least one of a list of storage addresses of the data storage medium that have previously been written and an indicator of a next address to write to the data storage medium, allow only a single write to ones of the storage addresses of the data storage medium that have previously been written and direct further write operations to at least the next address, and reject incorporation of firmware comprising further program instructions that support writing to storage data storage locations of the data storage medium more than one time by the write operations.

This Overview is provided to introduce a selection of concepts in a simplified form that are further described below in the Technical Disclosure. It may be understood that this Overview is not intended to identify key features or essential features of the claimed subject matter, nor is it intended to be used to limit the scope of the claimed subject matter.

### BRIEF DESCRIPTION OF THE DRAWINGS

Many aspects of the disclosure can be better understood with reference to the following drawings. While several implementations are described in connection with these drawings, the disclosure is not limited to the implementations disclosed herein. On the contrary, the intent is to cover all alternatives, modifications, and equivalents.

FIG. 1 illustrates a storage system in accordance with embodiments of the present disclosure.

FIG. 2 illustrates a storage assembly in accordance with embodiments of the present disclosure.

FIG. 3 illustrates a device or medium in accordance with embodiments of the present disclosure.

FIG. 4 illustrates a storage assembly in accordance with embodiments of the present disclosure.

FIG. 5 illustrates a flowchart of an address monitoring process in accordance with embodiments of the present disclosure.

FIG. 6A illustrates a flowchart of a fixed address monitoring process in accordance with a first embodiment of the present disclosure.

FIG. 6B illustrates a flowchart of a fixed address monitoring process in accordance with a second embodiment of the present disclosure.

FIG. 6C illustrates a flowchart of a fixed address monitoring process in accordance with a third embodiment of the present disclosure.

FIG. 7A illustrates erase command removal from sequencer microcode in accordance with embodiments of the present disclosure.

FIG. 7B illustrates erase command detection/rejection using sequencer microcode in accordance with embodiments of the present disclosure.

FIG. 8A illustrates erase command restructuring in microcode in accordance with embodiments of the present disclosure.

FIG. 8B illustrates erase functionality one-time removal in accordance with embodiments of the present disclosure.

FIG. 9 illustrates a flowchart of a firmware download check process in accordance with embodiments of the present disclosure.

FIG. 10 illustrates system area management updates in accordance with embodiments of the present disclosure.

FIG. 11 illustrates a dedicated writeable test area of data storage media in accordance with embodiments of the present disclosure.

FIG. 12A illustrates a flowchart of a read disturb process in accordance with a first embodiment of the present disclosure.

FIG. 12B illustrates a flowchart of a read disturb process in accordance with a second embodiment of the present disclosure.

FIG. 13 illustrates integration of program instructions with an IP Core environment in accordance with embodiments of the present disclosure.

### DETAILED DESCRIPTION

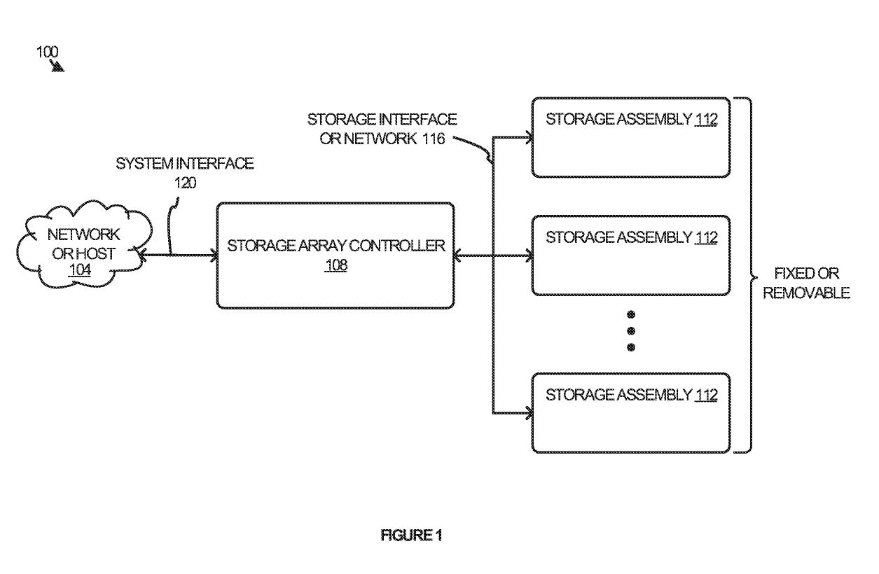

The following figures and description describe various embodiments that may be used to provide physical device security as well as enforcing one-time data writes and erasure prevention for WORM devices of the present disclosure. FIG. 1 illustrates a storage system 100 in accordance with embodiments of the present disclosure. Storage system 100 includes at least one network or host 104, one or more storage array controllers 108, and one or more storage assemblies 112. Many arrangements of storage system 100 are possible, in the illustrated arrangement should be viewed as only one of many such possible arrangements.

Network or host 104 represents any combination of networks or host computers. Networks 104 may include storage area networks (SANs), wide area networks (WANs), local area networks (LANs), or any other form of public or private networks 104. Network or host 104 may also represent one or more host computers, including a single host computer directly connected to storage array controller 108. In some embodiments, a host computer 104 may physically include one or more storage array controllers 108. Network or host 104 additionally represents sources of read and write operations to storage array controller 108. Network or host 104 connects to storage array controllers 108 through system interface 120, which is any suitable network or host interface. System interface 120 includes, but is not limited to, Ethernet, FIBER CHANNEL, SCSI, SAS, SATA, ESCON, FICON, ATM, or INFINIBAND.

Storage array controller 108 represents one or more storage array controllers 108, and aggregates multiple storage assemblies 112. Storage array controller 108 provides functions such as scalability, redundancy, virtualization, storage data distribution across multiple devices, and interface/protocol conversion. In some embodiments, storage array controller 108 may be optional in the system 100 since storage assemblies 112 may also directly connect to a host, server, or network. In some embodiments, storage array controller 108 is one or more redundant array of inexpensive devices (RAID) controllers. Storage array controllers 108 interface with storage assemblies 112 through a storage interface or network 116. Storage interface or network 116 may be the same or different than system interface 120, and any number of protocols and connections may be supported in either interface 116, 120.

Storage assemblies 112 include physical data storage media and at least low-level control circuits for the physical data storage media. Storage assemblies 112 include storage assembly interfaces in order to connect to storage array controllers 108 or network or host 104. The storage assembly interface can be any type of physical interface and protocol suitable for storage communications. Multiple ports, interfaces, and protocols may be supported. The storage assemblies 112 or physical data storage media may be fixed or removable.

Other implementations of WORM data storage may be implemented at the storage array controller level 108, but these are not secure since the storage assembly 112 may be removed and inserted into another system and have the data erased or modified. Therefore, the present disclosure implements WORM functionality within the storage assemblies 112 and not at higher levels where the data may be compromised.

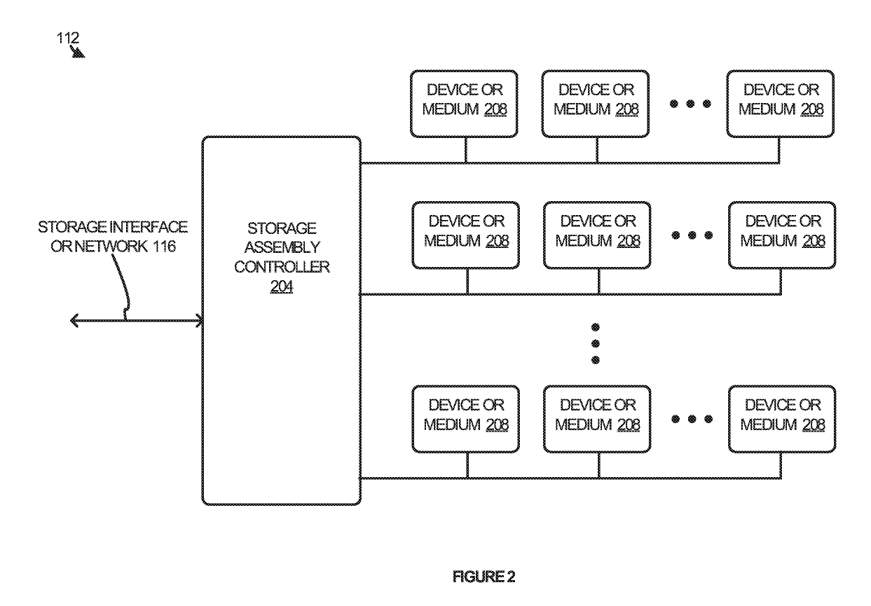

FIG. 2 illustrates a storage assembly 112 in accordance with embodiments of the present disclosure. Storage assembly 112 includes one or more storage assembly controllers 204 and one or more device or medium 208. In most embodiments, storage assembly 112 includes one storage assembly controller 204 and multiple device or medium 208. Storage assembly controller 204 interfaces to storage array controllers 108 through storage interface or network 116.

The storage assembly 112 employs a storage assembly controller 204 to manage the storage media 208 and interface to the outside world. Storage assembly controller 204 includes a controller processor 408 and controller firmware 412. The controller firmware 412 includes computer-readable instructions executed by the controller processor 408 that allows the controller processor 408 to control operation of the storage assembly 112. The storage assembly controller 204 has many functions including, but not limited to converting between the direct medium 208 interface and standard storage interfaces 116 and command protocols, organizing write data across the media array, implementing data encoding, error correction, and recovery for data integrity, and overall media management such as usage, life, power, quality, capacity, and performance.

There are two necessary conditions that need to be satisfied to meet WORM compliance: protection against medium access, and data modification prevention. There must be protections against direct access to the medium to prevent replacement or circumventing the controller function and modifying data in the data storage medium. Data modification prevention prevents erase or overwrite of stored data.

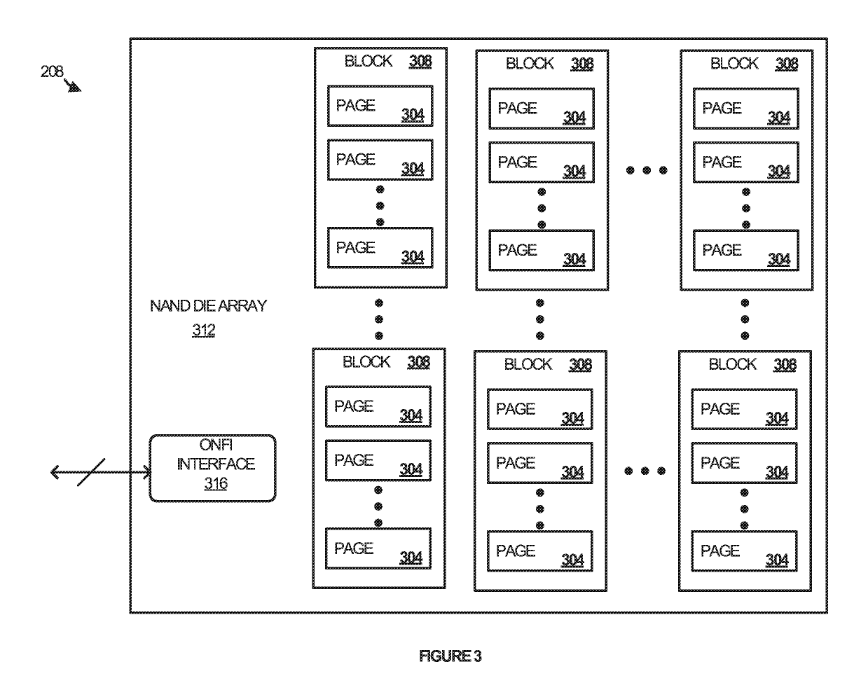

FIG. 3 illustrates a device or medium 208 in accordance with embodiments of the present disclosure. The illustrated medium includes a NAND die array 312, although other forms of media may be used as well. Media include, but are not limited to, NAND flash, NOR flash, HDD (Hard Disk Drives), and PCM (Phase Change Memory). The Storage Assembly 112 may or may not be removable in the system.

A NAND flash Storage Assembly 208 includes a controller and an array of NAND devices 312. NAND flash nonvolatile storage devices are organized as an array of memory cells surrounded by control logic to allow it to be programmed, read, and erased. The cells in a typical flash array are organized in pages 304 for write and read operations. Multiple pages 304 are in a block 308 and usually must be written sequentially within a block 308. Erase operations are done on a block 308 basis. A NAND die array 312 may include any number of blocks 308 and pages 304. Similarly, a single device or medium 208 may include any number of hard disk drives, NOR flash, or phase change memory devices.

The page 304, block 308, and array 312 sizes vary by flash die. Typical sizes at the time of this disclosure are 16 KB pages 304, 512 pages per block 308, and 1024 blocks per die. These sizes continue to grow as NAND die increase capacity.

The NAND die array 312 is controlled via interface 316. In one embodiment, interface 316 is an industry standard ONFI (Open NAND Flash Interface) specification. The ONFI specification includes both the physical interface 316 and the command protocol. The interface 316 has an 8 bit bus and enables a controller to perform program, read, erase, and associated operations to operate the NAND die. In another embodiment, the interface 316 uses a “toggle” interface. Multiple die can share an Interface 316 bus. In order to increase storage capacity and density, multiple die are often packaged together. A package may have one or more ports in an interface 316.

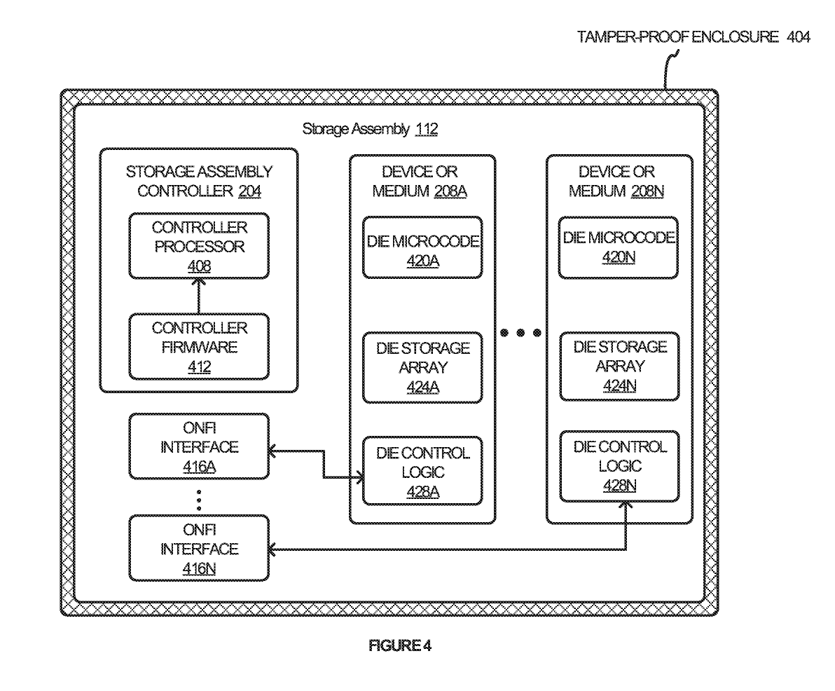

FIG. 4 illustrates a storage assembly 112 in accordance with embodiments of the present disclosure. In most embodiments, each storage assembly 112 is packaged separately from other storage assemblies 112 to facilitate modularity and fail device replacement.

Physical security for each storage assembly 112 needs to be assured. Each physical medium 208 must be sealed in the storage assembly 112 or attached to the storage assembly 112 in such a way that it cannot be removed, modified and re-installed, or replaced without either damage or detection. Preferably, each storage assembly controller 204 is also sealed within the storage assembly 112.

In a first option, media installed in package or die form (such as flash devices) may be coated or encased with an epoxy or other resin that cannot be removed without obvious evidence or damaging the device. There are methods of dissolving an epoxy coating, however, so as an added protection a signature (like a stamp, color or color combination, or pattern) or that is difficult to duplicate but easily inspected visually may be provided as part of the coating or encapsulation process.

In a second option, the storage assembly 112 may be housed in a tamper-proof, or tamper-evident enclosure 404 that can be visually inspected to detect physical intrusion. The enclosure may be plastic or sheet metal casing with permanent fasteners, and/or a tape or sticker seal that must be broken to remove the casing or enclosure. Permanent fasteners include rivets, non-removable screws, permanent glues, and any other fastener intended to at least discourage if not prevent disassembly. Although FIG. 4 illustrates a tamper-proof enclosure 404 for the storage assembly 112, it should be understood that any of the alternatives for physical security applicable to storage assembly 112 may be used within the spirit of the present application.

A third option may be used for media that requires high precision, calibration, or controlled atmosphere—such as magnetic hard disks. In this case, the media is already sealed in a tamper-proof enclosure. Options 1 & 2 above apply to any storage assembly 112 that is packaged and assembled onto a PCBA—such as NAND. Options 2 & 3 apply to storage assemblies 112 including hard disk drives is the data storage medium.

There are multiple ways to implement WORM functionality within the storage assembly 112. They range from hardware to firmware solutions and have varying levels of data modification security. They also have varying levels of implementation complexity and side effects that have to be resolved or managed. Most of the problems that have to be addressed are common across multiple implementations. The WORM options are organized by which area of the storage assembly 112 they are implemented in. The areas are storage assembly controller firmware 412, controller interfaces 416, die microcode 420, die control logic 428, and die storage arrays 424.

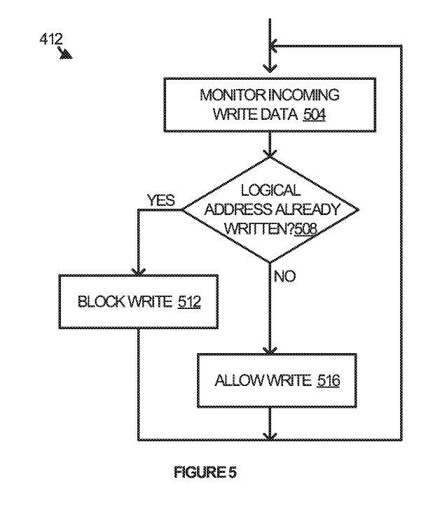

FIG. 5 illustrates a flowchart of an address monitoring process in accordance with embodiments of the present disclosure. The flowchart illustrates computer-readable instructions contained within controller firmware 412 within storage assembly 112. Flow begins at block 504.

At block 504, the controller processor 408 monitors incoming write data over storage interface or network 116. Flow proceeds to decision block 508.

At decision block 508, the controller processor 408 determines if a logical address corresponding to the incoming write data has been already written to storage media 208. In one embodiment, the storage assembly controller 204 maintains a list of all addresses in the devices or medium 208 that have already been written, and rejects write operations having the same address as any address in the list. In another embodiment, the storage assembly controller 204 writes data sequentially to addresses of the devices or medium 208 and maintains a watermark or indicator to the next available write address. As long as a next write address is available and the write operation data will fit within the available space in the devices or medium 208, the write operation can proceed. Otherwise, the write operation will be rejected. Because storage assembly 112 is a WORM device, only a single write is allowed to each address. Therefore, if the logical address has not already been written, then flow proceeds to block 516. Correspondingly, if the logical address has already been written, then flow proceeds to block 512.

At block 512, the write to the storage media 208 is blocked. Flow proceeds to block 504 to wait for next incoming write data.

At block 516, the write to the storage media 208 is allowed. Flow proceeds to block 504 to wait for next incoming write data.

A characteristic of firmware-based embodiments is that the final WORM firmware 412 can be loaded as a last step in the manufacturing process of storage assembly 112 so that there is no difference in manufactured hardware between the non-WORM and WORM supported storage assemblies 112.

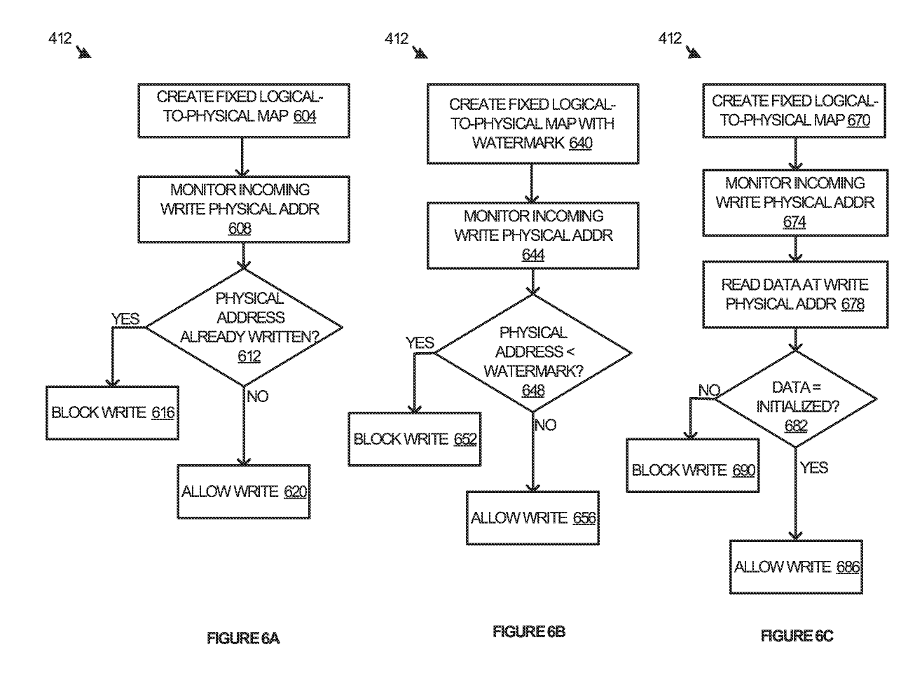

FIG. 6A illustrates a flowchart of a fixed address monitoring process in accordance with a first embodiment of the present disclosure.

In options using fixed addressing (FIGS. 6A-6C), the controller firmware 412 monitors the incoming write data. The write data normally includes numbered logical blocks, but may have other forms. In every case, there is an address associated with the write data.

In the embodiment shown in FIG. 6A, by using a table, range algorithm, or other method, the controller firmware 412 keeps track of the logical addresses that have been written. If a duplicate appears, the controller firmware 412 rejects the write. Flow begins at block 604.

At block 604, the controller processor 408 creates a fixed logical-to-physical map of addresses. Therefore, if a logical address and size of the write is known, the physical addresses corresponding to the logical address and size will also be known. Flow proceeds to block 608.

At block 608, the controller processor 408 monitors incoming write data physical addresses. Flow proceeds to decision block 612.

At decision block 612, the controller processor 408 determines if physical addresses corresponding to the incoming write data has been already written to storage media 208. Because storage assembly 112 is a WORM device, only a single write is allowed to each address. Therefore, if the physical address has not already been written, then flow proceeds to block 620. Correspondingly, if the physical address has already been written, then flow proceeds to block 616.

At block 616, the write to the storage media 208 is blocked. Flow ends at block 616.

At block 620, the write to the storage media 208 is allowed. Flow ends at block 620.

This embodiment allows full read/write/erase within the system area 1004 so that table updates, firmware updates, statistics, etc. can be treated the same as for non-WORM implementations. This option works for both NAND and hard disk drive storage technologies.

FIG. 6B illustrates a flowchart of a fixed address monitoring process in accordance with a second embodiment of the present disclosure. In the embodiment shown in FIG. 6B, by using a watermark and pointer, the controller firmware 412 keeps track of the logical addresses that have been written. If a duplicate appears, the controller firmware 412 rejects the write. Flow begins at block 640.

At block 640, the controller processor 408 creates a fixed logical-to-physical map of addresses, including a watermark. The watermark is identified by a pointer, which points to a first address of the device or media 208 being written, or a next available address for a device or media 208 has previously been written but is not yet full. Flow proceeds to block 644.

At block 644, the controller processor 408 monitors incoming write data physical addresses. Flow proceeds to decision block 648.

At decision block 648, the controller processor 408 determines if physical addresses corresponding to the incoming write data are at or above the watermark. Because storage assembly 112 is a WORM device, only a single write is allowed to each address. Therefore, if the physical address is at or above the watermark it has not already been written, and flow proceeds to block 656. Correspondingly, if the physical address is below the watermark it has already been written, and flow proceeds to block 652.

At block 652, the write to the storage media 208 is blocked. Flow ends at block 652.

At block 656, the write to the storage media 208 is allowed. Flow ends at block 656.

NAND-based devices are typically written sequentially. If the write algorithm is sequential, then the WORM enforcement algorithm just needs to detect if the requested physical address write is less that the next available physical address to be written—indicating it has been written. If a duplicate write is detected, it is rejected. This embodiment also allows rewrite or erase access to the system area 1004. It can also work for both hard disk drive and NAND-based technologies.

FIG. 6C illustrates a flowchart of a fixed address monitoring process in accordance with a third embodiment of the present disclosure. In this option, the controller 204 reads data at the physical address prior to writing to see if it has already been written. For NAND-based technology, an erased area is read back as all 1′s. For hard disk drive or other technologies that do not have an inherent secure erase function like NAND memory, this algorithm leverages the medium securely erased prior to WORM use to indicate that it has not been written.

If the WORM enforcement function detects a non-erased area prior to writing, it rejects the write command This algorithm must be designed to be compatible with the medium defect detection algorithm to ensure that a medium defect is not misinterpreted as a written area. This is sufficient for hard disk drives 208.

For NAND-based technology, the WORM enforcement must also reject any erase commands to physical addresses assigned to the user data area. Alternatively, the WORM firmware can have the erase command omitted from the design.

For overwrite technologies and the NAND-based embodiment that just prevents rewrites and erases to the physical addresses mapped to user data space, the system area 1004 is still erasable and used as normal. For embodiments that eliminate the erase function from the firmware 412, the system area 1004 needs to be treated as WORM as well. Flow begins at block 670.

At block 670, the controller processor 408 creates a fixed logical-to-physical map of addresses. Therefore, if a logical address and size of the write is known, the physical addresses corresponding to the logical address and size will also be known. Flow proceeds to block 674.

At block 674, the controller processor 408 monitors incoming write data physical addresses. Flow proceeds to block 678.

At block 678, the controller processor 408 reads data at the physical addresses corresponding to the received write operation. Flow proceeds to decision block 682.

At decision block 682, the controller processor 408 determines if the read data reflects if initialized data was previously written. In the case of NAND-based memory 208, data is typically initialized to be read back as all ones. In other embodiments, the data may be initialized to be read back is all zeros or as predetermined data pattern of ones and zeros. If a predetermined data pattern is employed, the pattern should be selected in order to not inadvertently match incoming data, along with any associated header, Error Correction Code (ECC), or various other fields written with the incoming data. If the read data corresponds to the predetermined data pattern, the physical address has not already been written and flow proceeds to block 686. Correspondingly, if the read data does not correspond to the predetermined data pattern, the physical address has already been written and flow instead proceeds to block 690.

At block 686, the write to the storage media 208 is allowed. Flow ends at block 686.

At block 690, the write to the storage media 208 is blocked. Flow ends at block 690.

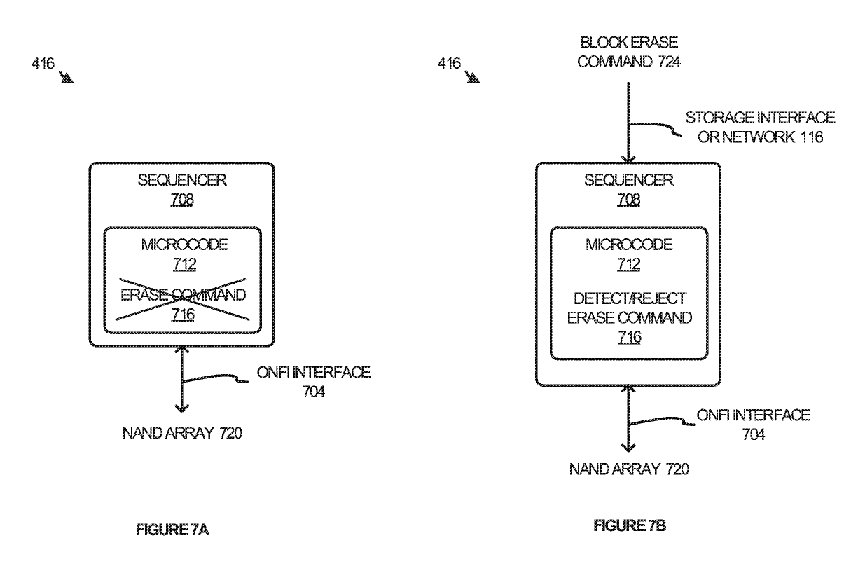

FIG. 7A illustrates erase command removal from sequencer microcode in accordance with embodiments of the present disclosure. The embodiments of FIGS. 7A-7B are specific to NAND-based arrays or other storage technology that has an intelligent, command based interface to the media. ONFI is one standard interface and protocol for controlling NAND-based memory devices and is used as an example in this section. The storage assembly controller 204 uses one or more ports of an interface 704 to control a NAND-based array 720.

Interface 704 port control may includes an intelligent sequencer 708 to generate, queue, and send commands and to receive responses. The sequencer 708 increases the performance of the NAND array 720 especially since a lot of functions on the port are polled. For those implementations using sequencers 708, there are embodiments to enforce WORM operation.

Most sequencers 708 include a small custom or standard microprocessor to control the command interface 704. Typically, the microcode 712 to operate an interface processor is downloaded to a small memory area by the controller firmware 412. In the embodiment illustrated in FIG. 7A, an erase command 716 is eliminated from the microcode 712. This option employs secure download and update support to prevent new sequencer microcode 712 supporting erases to replace the intended WORM microcode 712. Sequence-based WORM is a more secure implementation than the controller firmware based versions, but it does have to deal with WORM system area 1004 issues.

FIG. 7B illustrates erase command detection/rejection using sequencer microcode 708 in accordance with embodiments of the present disclosure. In this embodiment, the hardware sequencer 708 and ONFI block is designed to detect and reject ONFI block erase commands 724 OR to not have the functionality to form an ERASE command 716. In this embodiment, the hardware must have access to and be aware of the ONFI commands This works best in embodiments where the hardware portion of the ONFI block generates the ONFI commands This implementation removes the erase functionality permanently from the controller and makes the controller WORM-only. This is a very secure WORM embodiment as there is no way to defeat it with rogue firmware or microcode 712.

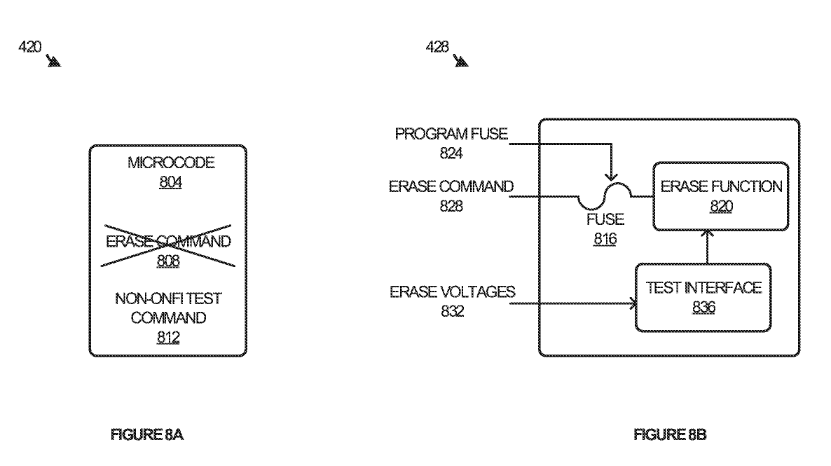

FIG. 8A illustrates erase command restructuring in microcode 804 in accordance with embodiments of the present disclosure. The embodiments shown in FIGS. 8A and 8B move the WORM functionality into the actual memory array. This applies to NAND-based or any other storage technology that employs an intelligent command interface to be integrated with it. There are multiple implementations with varying levels of WORM security and complications. These are the most secure WORM implementations.

NAND dice includes small microprocessors to manage the protocols and commands. The microcode 804, as with the controller sequencer microcode, is designed with support for the erase command removed 806 and rejected on the interface. For this embodiment, a special test command 812 should be included in the firmware 804 that is not ONFI compliant to support erases during die and packaged die testing.

FIG. 8B illustrates erase functionality one-time removal in accordance with embodiments of the present disclosure. The NAND-based array control circuitry on the NAND die performs the necessary control functions to perform page programs, page reads, and block erases as well as other functions to maintain the cell array. This embodiment involves a design feature added to the control circuitry of the die to disable block erases 828. Although this is a very secure WORM method, it makes manufacturing test of NAND dice difficult to impossible. The preferred method is to include a one-time programmable fuse 816 or one time programmable bit cell in a register in the array that logically disables the erase function 820 in the control block.

Doing this allows the die and assembled multi-die packages to go through normal test processes. Once they have passed, then the fuse 816 can be blown 824 or the OTP bit set to disable erases making the part WORM-only. If the fuse or OTP access is made securely, such as through test equipment only, then rewritable and WORM NAND can share the same design and processes.

The erase circuitry in a NAND-based array uses block selection as well as elevated erase voltages 832 among other design features. This option makes the WORM and rewritable versions of NAND-based storage separate designs. To support this method, alterations in the die and packaged die test process are necessary to verify that the array is good. One embodiment is for the test system to supply the erase voltages 832 directly in order to run the tests, thus disallowing erases outside of that environment. The test interface 836 can be designed to have erase voltages 832 applied at block locations allowing the erase voltage 832 distribution circuits to be removed from the die.

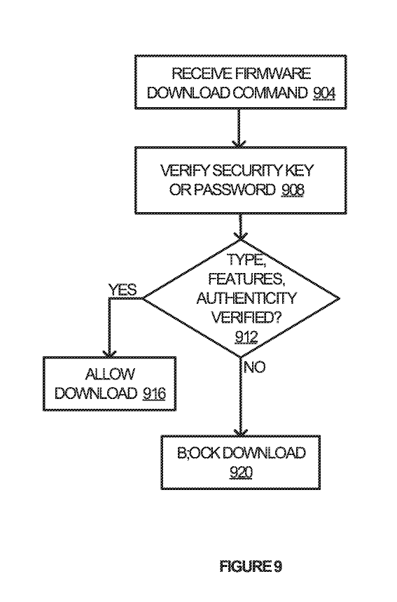

FIG. 9 illustrates a flowchart of a firmware download check process in accordance with embodiments of the present disclosure. Any WORM implementation performed in firmware 412 can use firmware download security and compatibility checking to ensure that non-WORM firmware or rogue firmware isn't loaded into the controller to defeat the WORM functionality. Flow begins at block 904.

At block 904, a storage assembly controller 204 receives a firmware download command. Flow proceeds to block 908.

At block 908, the controller processor 408 verifies a security key or password as part of the firmware download command For relatively complex firmware, it is desirable to support field upgrades to fix bugs, minimize returns, and reduce the chance of lost or corrupted data. If firmware upgrades are supported, it is important to implement a secure algorithm involving a security key, secure password, or other highly difficult to defeat feature that prevents unauthorized firmware downloads. Flow proceeds to decision block 912.

At decision block 912, the controller processor 408 determines if the type, features, and authenticity of the firmware download command are all verified. The type of firmware download command must correspond to controller firmware 412. The features of the firmware download command must include WORM compliance for both data write and data erase operations. The authentication of the firmware download command verifies that the version and integrity of the firmware download command are correct. If the type, features, and authenticity of the firmware download command have been verified, then flow proceeds to block 916. If either the type, features, or authenticity of the firmware download command have not been verified, then flow instead proceeds to block 920.

At block 916, the controller processor 408 has verified the type, features, and authenticity of the firmware download command, and allows the firmware download to proceed. Flow ends at block 916.

At block 920, at least one of the type, features, and authenticity of the firmware download command have not been verified, and the download is blocked. Flow ends at block 920.

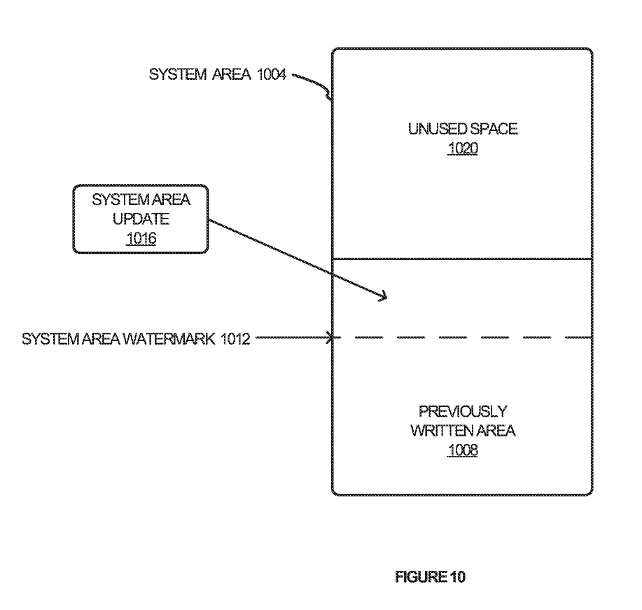

FIG. 10 illustrates system area 1004 management updates in accordance with embodiments of the present disclosure. Typically, most storage systems have a system area 1004 that is used for manufacturing parameters, operational parameters, medium defect identification, medium operation, statistics, logs, firmware images, microcode images, etc. These areas are normally used by the storage assembly controller 204 to boot, setup and operate the system, optimize medium usage, performance, and life, determine how to communicate with host computers, and store error and logging information. The system area 1004 is not normally accessible external except via special commands

Many of the WORM embodiments do not support erase or rewrites in the system area 1004. For such embodiments, the system area 1004 needs to be treated as “append only” and can never be erased. One embodiment to manage the system area 1004 is shown in FIG. 10, where a relatively large system area 1004 is shown. System area 1004 includes a previously written area 1008, which may not be overwritten. A system area watermark or indicator 1012 identifies the boundary between the previously written area 1008 and unused space 1020. A system area update 1016 is appended to the area immediately above the system area watermark 1012, correspondingly reducing the amount of unused space 1020 in the system area 1004. Additional system area updates 1016 may be appended in the remaining unused space 1020, as long as space is available.

System area 1004 firmware algorithms need to be able to read history in the system area 1004 and ignore outdated, non-erasable information. Maintaining such history may eliminate the need for a system area watermark 1012 as long as the history includes addresses used for previous system area updates 1016 in the previously written area 1008. Also, this normally requires a larger system area 1004 which will eventually fill up after append operations. The algorithms should also be judicious in system area 1004 use since it is finite. Once the system area 1004 is full, the drive still operates in a read only mode. However, additional firmware downloads, nonvolatile mode parameter changes, statistics updates, etc. will no longer be supported.

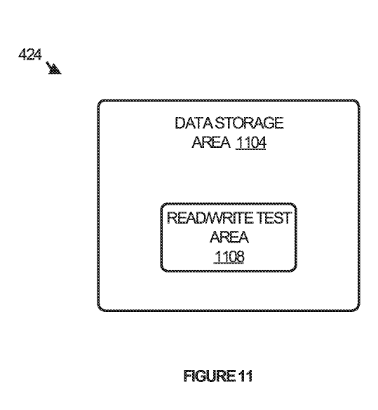

FIG. 11 illustrates a dedicated writeable test area 1108 of data storage media 424 in accordance with embodiments of the present disclosure. The manufacturing test and qualification process for NAND-based storage arrays normally consist of die level test, packaged die test, and assembly level testing with the controller. Current processes for erasable systems assume that the storage array can be written, verified, and erased at any step in the process. The WORM implementations in this embodiment are intended to be compatible with die level and packaged die test processes currently in use. Some of this testing may employ additional support circuitry on the test system in order to support erase functionality.

For systems that implement the WORM functionality on the storage assembly controller, the manufacturing and test process for the storage array components doesn't change. The components include the bare die and packaged die testing. Since the controller cannot erase the storage array, the die level testing needs to be relied on for qualification and bad block detection. After assembly of the storage assembly 112, there may be a desire to perform a simple write/read test to ensure it is functional. A test area 1108 can be set aside in the die 1104 to allow a write/read verify test without changing or upsetting system operation in non-test environments.

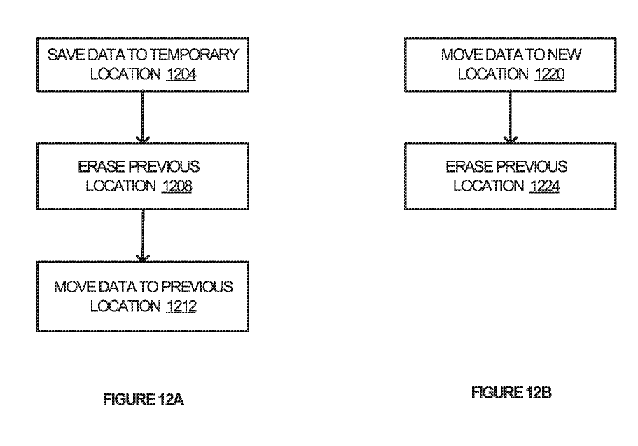

FIG. 12A illustrates a flowchart of a read disturb process in accordance with a first embodiment of the present disclosure. For NAND-based flash, read disturb may be a consideration for WORM mode. Read disturb is the term for a read degradation that occurs after hundreds or thousands of reads to a specific location. This degradation is corrected by an erase and rewrite of the data. The save, erase, and rewrite can be done in place or to a new block. Once refreshed by an erase, the block can again be read hundreds or thousands of times. In the embodiment illustrated in FIG. 12A, a save/erase/restore embodiment is illustrated. Flow begins at block 1204.

At block 1204, data in a specific page 304 or block 308 is saved to a temporary location. Flow proceeds to block 1208.

At block 1208, the previous location is erased. This restores the cells at the previous location, which renders the data able to be reliably read for many future cycles. Flow proceeds to block 1212.

At block 1212, the data in the temporary location is restored to the previous location following erasure. Flow ends at block 1212.

It should be noted that versions of the WORM embodiments that have WORM system areas 1004 cannot keep track of read counts, so the read disturb avoidance algorithm can't easily be implemented. It is important to keep in mind that WORM tape can only be read a few hundred times at best—so not including read disturb avoidance is not a significant issue.

FIG. 12B illustrates a flowchart of a read disturb process in accordance with a second embodiment of the present disclosure. In the embodiment illustrated in FIG. 12B, a data move embodiment is illustrated. Flow begins at block 1220.

At block 1220, data in an original location is moved to a new location, from where the data will be accessed from now on. Flow proceeds to block 1224.

At block 1224, the original location is erased. In some embodiments, the original location may be reused for new data storage, and in other embodiments, the original location is either not erased or not reused. Flow ends at block 1224.

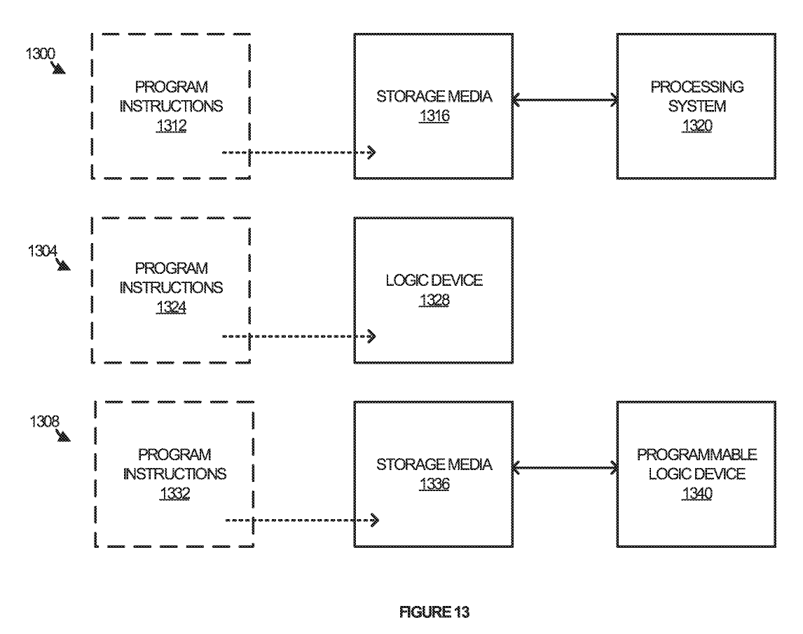

FIG. 13 illustrates integration of program instructions with a semiconductor intellectual property (IP) core environment in accordance with embodiments of the present disclosure. WORM architectures 1312-1332 can comprise any of the storage architecture examples discussed herein. In some embodiments, the present disclosure may be realized as an IP core downloadable or transferrable to various structures.

In a first instantiation 1300, an IP core described as program instructions comprising WORM architecture 1312 may be downloaded to a storage media 1316. A processing system 1320 accesses the storage media in order to perform the various processes described herein. In this example, WORM architecture 1312 is stored on storage media 1316. Processing system 1320 communicates with storage media 1316 to retrieve WORM architecture 1312 from storage media 1316.

Processing system 1320 can comprise one or more microprocessors and other circuitry that retrieves and executes WORM architecture 1312 from storage media 1316. Processing system 1320 can be implemented within a single processing device but can also be distributed across multiple processing devices or sub-systems that cooperate in executing program instructions. Examples of processing system 1320 include general purpose central processing units, application specific processors, and logic devices, as well as any other type of processing device, combinations, or variations thereof.

Storage media 1316 can comprise any non-transitory computer readable storage media readable by processing system 1320 and capable of storing WORM architecture 1312. Storage media 1316 can include volatile and nonvolatile, removable and non-removable media implemented in any method or technology for storage of information, such as computer readable instructions, data structures, program modules, or other data. In addition to storage media, in some implementations storage media 1316 can also include communication media over which WORM architecture 1312 can be communicated. Storage media 1316 can be implemented as a single storage device but can also be implemented across multiple storage devices or sub-systems co-located or distributed relative to each other. Storage media 1316 can comprise additional elements, such as a controller, capable of communicating with processing system 1320. Examples of storage media include random access memory, read only memory, magnetic disks, optical disks, flash memory, virtual memory and non-virtual memory, magnetic cassettes, magnetic tape, magnetic disk storage or other magnetic storage devices, or any other medium which can be used to store the desired information and that can be accessed by an instruction execution system, as well as any combination or variation thereof, or any other type of storage media. In no case is the storage media a propagated signal.

WORM architecture 1312 can be implemented in program instructions and among other functions can, when executed by processing system 1320, direct processing system 1320 to operate storage devices and write data to storage media, among other operations as discussed herein. Additional software can be included on storage media 1316, and can include additional processes, programs, or components, such as operating system software, database software, or application software. WORM architecture 1312 can also comprise firmware or some other form of machine-readable processing instructions executable by processing system 1320.

In general, WORM architecture 1312 can, when loaded into processing system 1320 and executed, transform processing system 1320 overall from a general-purpose computing system into a special-purpose computing system customized to operate storage devices and write data to storage media, among other operations. Encoding WORM architecture 1312 on storage media 1316 can transform the physical structure of storage media 1316. The specific transformation of the physical structure can depend on various factors in different implementations of this description. Examples of such factors can include, but are not limited to the technology used to implement the storage media of storage media 1316 and whether the computer-storage media are characterized as primary or secondary storage. For example, if the computer-storage media are implemented as semiconductor-based memory, WORM architecture 1312 can transform the physical state of the semiconductor memory when the program is encoded therein. For example, WORM architecture 1312 can transform the state of transistors, capacitors, or other discrete circuit elements constituting the semiconductor memory. A similar transformation can occur with respect to magnetic or optical media. Other transformations of physical media are possible without departing from the scope of the present description, with the foregoing examples provided only to facilitate this discussion.

In a second instantiation 1304, an IP core described as program instructions comprising worm architecture 1324 may be downloaded to a logic device 1328. The logic device 1328 may be a field programmable gate array (FPGA) or other known logic structure suitable for direct programming from the program instructions 1324. In this example, WORM architecture 1324 is implemented in logic device 1328. Logic device 1328 can comprise a fabricated logic device, an application specific integrated circuit (ASIC) device, application-specific standard products (ASSP), or other integrated circuit device. In some examples, WORM architecture 1324 is implemented in one or more discrete logic devices which comprise logic device 1328. Logic device 1328 can include logic, logic gates, combinatorial logic, sequential logic, signal interconnect, transmission circuitry, clock circuitry, or other elements implemented in one or more semiconductor devices.

Finally, in a third instantiation 1308, an IP core described as program instructions comprising worm architecture 1332 may be downloaded to a storage media 1336. A programmable logic device 1340 may interface with the storage media 1336 order to program the programmable logic device 1342 perform the various processes described herein. In this example, WORM architecture 1332 is stored on storage media 1336. Programmable logic device 1340 communicates with storage media 1336 to retrieve WORM architecture 1332 from storage media 1336.

Programmable logic device 1340 can comprise a field programmable gate array (FPGA) which can include configurable logic blocks (CLB), look up tables (LUT), buffers, flip flops, logic gates, input/output circuitry, or other elements packaged in one or more semiconductor devices. Programmable logic device 1340 can receive WORM architecture from storage media 1336 using a signaling interface, joint test action group (JTAG) serial interface, parallel interface, or other communication interface.

In this example, WORM architecture 1332 can comprise program instructions such as a netlist or binary representation which are stored on storage media 1336 and are capable of programming programmable logic device 1340. A source code representation of WORM architecture 1332 can be employed to create or distribute a ‘core’ which implements WORM architecture 1332 using a hardware description language (HDL) such as Verilog or very high speed integrated circuit hardware description language (VHDL). In source code form, WORM architecture 1332 is typically processed and transformed into a netlist representation suitable for further transformation via place-and-route and mapping processes to generate a gate-level binary representation suitable for programming a programmable logic device, such as an FPGA.

The binary form of WORM architecture 1332 is stored on storage media 1336. Storage media 1336 can comprise an electrically erasable programmable read only memory (EEPROM), static random access memory (SRAM), phase change memory, magnetic RAM, flash memory, or other non-transitory, non-volatile storage device. Typically, during a startup, power on, or boot process, programmable logic device 1340 reads the binary form of WORM architecture 1332, along with any other overhead and programming instructions, to program WORM architecture 1332 into programmable logic device 1340, including any associated input/output circuitry. Storage media 1336 can comprise elements discussed for storage media 1316.

The functional block diagrams, operational scenarios and sequences, and flow diagrams provided in the Figures are representative of exemplary systems, environments, and methodologies for performing novel aspects of the disclosure. While, for purposes of simplicity of explanation, methods included herein may be in the form of a functional diagram, operational scenario or sequence, or flow diagram, and may be described as a series of acts, it is to be understood and appreciated that the methods are not limited by the order of acts, as some acts may, in accordance therewith, occur in a different order and/or concurrently with other acts from that shown and described herein. For example, those skilled in the art will understand and appreciate that a method could alternatively be represented as a series of interrelated states or events, such as in a state diagram. Moreover, not all acts illustrated in a methodology may be required for a novel implementation.

The descriptions and figures included herein depict specific implementations to teach those skilled in the art how to make and use the best option. For the purpose of teaching inventive principles, some conventional aspects have been simplified or omitted. Those skilled in the art will appreciate variations from these implementations that fall within the scope of the disclosure. Those skilled in the art will also appreciate that the features described above can be combined in various ways to form multiple implementations. As a result, the invention is not limited to the specific implementations described above, but only by the claims and their equivalents.

1. A storage device, comprising:
a data storage medium comprising data storage locations; and
a controller, coupled to the data storage medium and configured to receive at least write operations for storage of data onto the data storage medium;
the controller further configured to provide a write-once mode of operation that prevents the data written to ones of the data storage locations of the data storage medium from being overwritten or erased by further data directed for storage to the ones of the data storage locations.

2. The storage device of claim 1, wherein at least one of the storage device comprises a tamper-proof enclosure comprising at least one of permanent fasteners and a seal that must be removed prior to opening the enclosure or the storage medium and the controller are encased in a permanent coating comprising a pattern, a stamp, or a color combination each allowing visual intrusion detection.

3. The storage device of claim 1, wherein the controller comprises:
a processor; and
a memory, coupled to the processor, comprising computer-readable instructions that when executed by the processor are configured to direct the processor to at least:
reject ones of the write operations directed to previously written addresses of the data storage medium; and
reject incorporation of firmware comprising further computer-readable instructions that support writing to locations of the data storage medium more than one time by the write operations.

4. The storage device of claim 3, wherein the computer-readable instructions are further configured to perform one of:
maintain an indicator of a next address to write to the data storage medium and direct further write operations to at least the next address; and
maintain a list of storage addresses of the data storage medium that have previously been written to allow only a single write to ones of the storage addresses of the data storage medium that have previously been written.

5. The storage device of claim 3, wherein the data storage medium is configured to be initialized with a predetermined data pattern prior to being written, wherein in response to receiving a write operation, the controller reads one or more data storage locations corresponding to the write operation and rejects the write operation if the one or more data storage locations does not contain the predetermined data pattern.

6. The storage device of claim 3, wherein the controller further comprises a sequencer and sequencer hardware to control the data storage medium, wherein the sequencer or sequencer hardware is configured to not include or support an erase command

7. The storage device of claim 1, wherein the data storage medium comprises at least one NAND storage cell array and microcode, wherein the microcode is configured to not support an erase command

8. The storage device of claim 1, wherein the data storage medium comprises at least one NAND storage cell array and a control circuit, wherein the control circuit comprises a one-time programmable bit or fuse configured to disable erase operations after the bit is blown or the fuse is written, respectively.

9. The storage device of claim 1, wherein the data storage medium is configured to provide erase voltages through one or more test interfaces to block locations instead of operational interfaces.

10. A storage controller, comprising:
a processor, configured to receive at least write operations directed to a data storage medium; and
a memory, coupled to the processor, comprising computer-readable instructions that when executed by the processor are configured to direct the processor to at least:
reject ones of the write operations directed to previously written addresses of the data storage medium; and
reject incorporation of firmware comprising further computer-readable instructions that support writing to data storage locations of the data storage medium more than one time by the write operations.

11. The storage controller of claim 10, wherein the controller and the data storage medium are encased in an epoxy coating comprising a pattern, a stamp, or a color combination allowing visual intrusion detection or mounted within a tamper-proof enclosure comprising at least one of permanent fasteners or a seal that must be removed prior to opening the enclosure.

12. The storage controller of claim 10, wherein the computer-readable instructions are further configured to perform one of:
maintain an indicator of a next address to write to the data storage medium and direct further write operations to at least the next address; and
maintain a list of storage addresses of the data storage medium that have previously been written to allow only a single write to ones of the storage addresses of the data storage medium that have previously been written.

13. The storage controller of claim 10, wherein the data storage medium is configured to be initialized with a predetermined data pattern prior to being written, wherein in response to receiving a write operation, the controller reads one or more data storage locations corresponding to the write operation and rejects the write operation if the one or more data storage locations does not contain the predetermined data pattern.

14. The storage controller of claim 10, wherein the data storage medium comprises at least one NAND storage cell array and microcode, wherein the microcode is configured to not support an erase command.

15. The storage controller of claim 14, wherein the data storage medium comprises at least one NAND storage cell array and a control circuit, wherein the control circuit comprises a one-time programmable bit or fuse configured to disable erase operations after the bit is blown or the fuse is written, respectively.

16. An apparatus, comprising:
one or more computer readable storage media;
program instructions stored on the one or more computer readable storage media that, based at least on being read and executed by a processing system, direct the processing system to at least:
receive at least write operations for storage of data onto an associated data storage medium;
maintain at least one of a list of storage addresses of the data storage medium that have previously been written, and an indicator of a next address to write to the data storage medium;
allow only a single write to ones of the storage addresses of the data storage medium that have previously been written and direct further write operations to at least the next address; and
reject incorporation of firmware comprising further program instructions that support writing to storage locations of the data storage medium more than one time by the write operations.

17. The apparatus of claim 16, wherein the apparatus is encased in an epoxy coating comprising a pattern, a stamp, or a color combination allowing visual intrusion detection or the apparatus is mounted within a tamper-proof enclosure comprising permanent fasteners and a seal that must be removed prior to opening the enclosure.

18. The apparatus of claim 16, wherein the program instructions are configured to initialize the data storage medium with a predetermined data pattern prior to being written, wherein in response to receiving a write operation, the program instructions are configured to read one or more data storage locations corresponding to the write operation and rejects the write operation if the one or more data storage locations does not contain the predetermined data pattern.

19. The apparatus of claim 16, the data storage medium comprising at least one NAND storage cell array and a control circuit, wherein the control circuit comprises a one-time programmable bit or fuse configured to disable erase operations after the bit is blown or the fuse is written, respectively.

20. The apparatus of claim 16, the data storage medium comprising a sequencer and sequencer microcode, wherein at least one of the sequencer and sequencer microcode is configured to perform at least one of:
block erase operations;
reject erase operations; and
be unresponsive to erase operations.
